(19) United States
(12) Patent Application Publication
(10) Pub. No.: US 2022/0336714 A1
(43) Pub. Date: Oct. 20, 2022

(54) DISPLAY APPARATUS

(71) Applicant: Samsung Display Co., Ltd., Yongin-si (KR)

(72) Inventor: Sangkuk KIM, Yongin-si (KR)

(73) Assignee: Samsung Display Co., Ltd., Yongin-si (KR)

(21) Appl. No.: 17/551,580

(22) Filed: Dec. 15, 2021

(30) Foreign Application Priority Data
Apr. 15, 2021 (KR) 10-2021-0049075

(51) Int. Cl. H01L 33/48; H01L 33/62

(52) U.S. Cl. CPC H01L 33/486; H01L 33/62

(57) ABSTRACT

A display apparatus includes a substrate; a cover window arranged on an upper surface of the substrate; a first circuit board that at least partially overlaps the substrate and is at least partially bendable; a cover layer at least partially overlapping the first circuit board; and a first protruding member arranged on a lower surface of the cover window.

### CROSS-REFERENCE TO RELATED APPLICATION(S)

This application claims priority to and the benefit of Korean Patent Application No. 10-2021-0049075 under 35 U.S.C. § 119, filed on Apr. 15, 2021, in the Korean Intellectual Property Office (KIPO), the entire contents of which are incorporated herein by reference.

### BACKGROUND

### 1. Technical Field

One or more embodiments relate to a display apparatus.

### 2. Description of the Related Art

Mobility-based electronic devices are widely used. As mobile electronic devices, tablet personal computers (PCs) have recently been widely used, in addition to compact electronic devices such as a mobile phone. These mobile electronic devices include a display apparatus to support various functions, for example, to provide visual information such as images or pictures to users.

A display apparatus may include a display panel realizing an image and a display driver controlling driving of the display panel. The display driver may be electrically connected to the display panel by using, for example, a chip on film (COF) method, a chip on glass (COG) method, or a chip on plastic (COP) method.

### SUMMARY

However, in display apparatuses according to the related art, static electricity (or electrostatic current) is transferred to wire to cause defects in the display apparatuses.

One or more embodiments provide a display apparatus in which a protruding member is included on a lower surface of a cover window to prevent or minimize transfer of static electricity (or electrostatic current) to wires. However, these objectives are just examples, and the scope of the present disclosure is not limited thereby.

Additional aspects will be set forth in part in the description which follows and, in part, will be apparent from the description, or may be learned by practice of the presented embodiments of the disclosure.

One or more embodiments include a display apparatus including a substrate, a cover window arranged on an upper surface of the substrate, a first circuit board that at least partially overlaps the substrate and is at least partially bendable, a cover layer at least partially overlapping the first circuit board, and a first protruding member arranged on a lower surface of the cover window.

The first protruding member may at least partially overlap the cover layer.

An end of the first protruding member and an end of the cover layer may be spaced apart from each other by a first distance in a direction perpendicular to the substrate.

The first protruding member may extend in a first direction.

The first protruding member may be spaced apart from a first edge of the cover window in a second direction intersecting the first direction.

The first protruding member may be integral with the cover window.

The first protruding member may include a conductive material.

The first circuit board may include a flexible film, a wire, and a display driver.

The display apparatus may further include a second circuit board arranged on a lower surface of the substrate.

The first circuit board may at least partially overlap the second circuit board.

The cover layer may at least partially overlap the second circuit board.

The cover layer may include a conductive material.

The display apparatus may further include a display panel between the substrate and the cover window.

The first protruding member may be spaced apart from the display panel in the second direction.

The display apparatus may further include a second protruding member arranged on the lower surface of the cover window.

The second protruding member may be spaced apart from the display panel.

The second protruding member may be integral with the cover window.

The second protruding member may include a conductive material.

The second protruding member may be integral with the first protruding member.

The display apparatus may further include a shielding film arranged on a lower surface of the substrate.

Other aspects, features, and advantages other than those described above will become apparent from the accompanying drawings, the appended claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a plan view schematically illustrating a display apparatus according to an embodiment;

FIG. 3 is a cross-sectional view schematically illustrating a display apparatus according to an embodiment;

FIG. 4 is a cross-sectional view schematically illustrating a bent state of the display apparatus of FIG. 3;

FIG. 5 is a cross-sectional view schematically illustrating a display apparatus according to an embodiment;

FIG. 6 is an equivalent circuit diagram of a pixel circuit included in a display apparatus according to an embodiment;

FIG. 7 is an enlarged view of region A of FIG. 4;

FIG. 8 is a plan view schematically illustrating a display apparatus according to an embodiment;

FIGS. 9A to 9C are cross-sectional views schematically illustrating a display apparatus according to an embodiment;

FIGS. 10A to 10E are diagrams for describing a schematic shape of a first protruding member of a display apparatus according to an embodiment;

FIG. 11 is a plan view schematically illustrating a display apparatus according to an embodiment; and

FIG. 12 is a cross-sectional view schematically illustrating a display apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The effects and features of the disclosure, and ways to achieve them will become apparent by referring to embodiments that will be described below in detail with reference to the drawings. However, the disclosure is not limited to the following embodiments but may be embodied in various forms.

It will be understood that although the terms “first,” “second,” and the like may be used herein to describe various elements, these elements should not be limited by these terms. These terms are only used to distinguish one element from another.

In the embodiments below, the singular forms include the plural meanings unless the context clearly indicates otherwise.

In the embodiments below, it is to be understood that the terms such as “including” or “having” are intended to indicate the existence of the features or elements disclosed in the specification, and are not intended to preclude the possibility that one or more other features or elements may be added.

In the embodiments below, it will be understood that when a portion such as a layer, an area, or an element is referred to as being “on” or “above” another portion, it can be directly on or above the other portion, or intervening portion may also be present.

Also, in the drawings, for convenience of description, sizes of elements may be exaggerated or contracted. For example, since sizes and thicknesses of elements in the drawings are arbitrarily illustrated for convenience of explanation, the following embodiments are not limited thereto.

In the specification, “A and/or B” refers to A, B, or A and B. In addition, “at least one of A and B” refers to A, B, or A and B.

In the embodiments below, when a wire is described as “extending in a first direction or a second direction,” it means that the wire extends not only in a straight line but also in a zigzag line or a curve in the first or second direction.

In the embodiments below, the term “on a plane” or “in a plan view” refers to a view of an object viewed from above, and “on a cross-section” refers to a view of a vertical cross-section of an object viewed from a side. In the embodiments below, when referred to as “overlapping,” this includes overlapping “on a plane” and “on a cross-section.”

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, the embodiments of the disclosure will be described in detail with reference to the accompanying drawings, and in the description with reference to the drawings, like reference numerals refer to like elements.

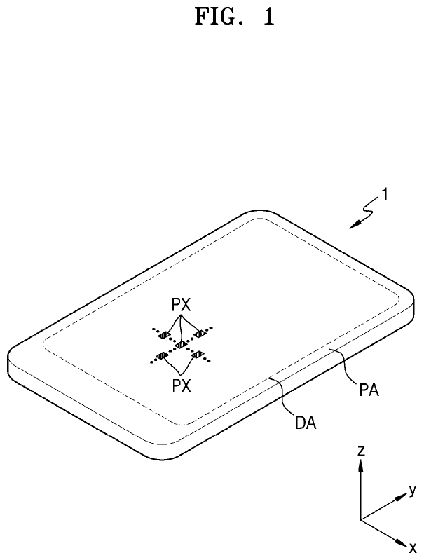

FIG. 1 is a perspective view schematically illustrating a display apparatus according to an embodiment.

Referring to FIG. 1, a display apparatus 1 may include a display area DA and a peripheral area PA outside the display area DA. The display apparatus 1 may provide an image by an array of pixels PX arranged two-dimensionally in rows and columns in the display area DA. Each pixel PX may be defined as an emission area from which a light-emitting element driven by a pixel circuit emits light. For example, an image may be provided by light emitted by the light-emitting element via the pixel PX. An area where an image is provided is determined by an arrangement of light-emitting elements, and thus, the display area DA may be defined by the light-emitting elements. In the display area DA, not only light-emitting elements and pixel circuits driving these but also various signal lines and power lines electrically connected to the pixel circuits may be arranged.

The peripheral area PA is an area where no image is provided, and the peripheral area PA may surround the display area DA entirely or partially. In the peripheral area PA, various wires, a driving circuit, or the like, for providing an electrical signal or power to the display area DA may be arranged.

The display apparatus 1 may have an approximately rectangular shape when viewed in a direction perpendicular to an upper surface of the display apparatus 1. For example, as illustrated in FIG. 1, the display apparatus 1 may have overall a rectangular planar shape having a short side extending in a first direction (e.g., an x-direction) and a long side extending in a second direction (e.g., a y-direction). A corner where the short side in the first direction (or x-direction) and the long side in the second direction (or y-direction) may have a rectangular shape or a round shape having a certain curvature as illustrated in FIG. 1. The planar shape of the display apparatus 1 is not limited to a rectangle and may have various shapes such as a polygonal shape, e.g., a triangular shape, a circular shape, an elliptical shape, an and/or amorphous shape.

Hereinafter, the display apparatus 1 including an organic light-emitting diode (OLED) as a light-emitting element is described, but the display apparatus 1 is not limited thereto. Various other modifications may also be made. In an embodiment, the display apparatus 1 may include an inorganic light-emitting diode or a quantum dot light-emitting diode as a light-emitting element.

The display apparatus 1 may be used as a display screen of not only portable electronic devices such as a mobile phone, a smartphone, a tablet personal computer (PC), a mobile communication terminal, an electronic notebook, an e-book, a portable multimedia player (PMP), a navigation device, an ultra-mobile PC, or the like, but also as a display screen of various products such as a television, a laptop computer, a monitor, an advertising board, and an Internet of Things (IoT) device. Also, the display apparatus 1 according to an embodiment may be used in wearable devices such as a smartwatch, a watchphone, a glasses-type display, and a head-mounted display (HMD). The display apparatus 10 according to an embodiment may be used as a center information display (CID) arranged at the instrument panel and the center fascia or the dashboard of a vehicle, as a room mirror display instead of the side-view mirrors of a vehicle, or as a display placed on the back of each of the front seats that is an entertainment system for passengers at the rear seats of a vehicle. Hereinafter, for convenience of description, the display apparatus 1 used in a smartphone will be described as an example.

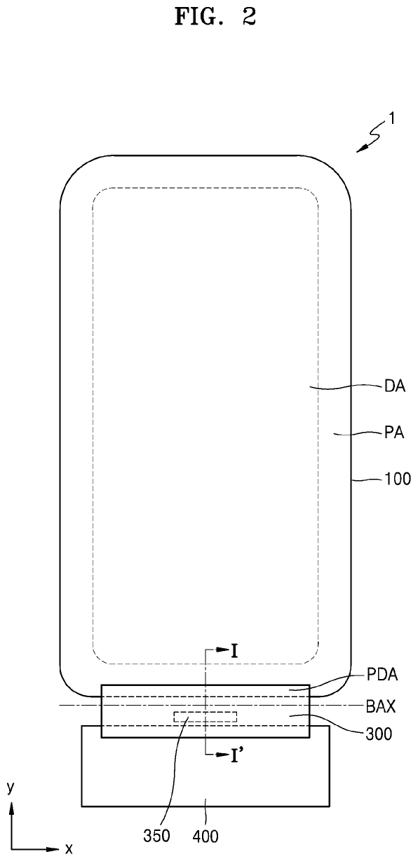

FIG. 2 is a plan view schematically illustrating a display apparatus according to an embodiment. A display panel 200 (FIG. 4) and a cover window 500 (FIG. 4) may be further arranged on an upper surface of a substrate 100 of FIG. 2, and they are omitted in FIG. 2 for convenience of description.

Referring to FIG. 2, the display apparatus 1 may include the display area DA and the peripheral area PA outside the display area DA. In an embodiment, the other regions than the display area DA may be the peripheral area PA in the display apparatus 1. In an embodiment, the peripheral area PA may include a pad area PDA arranged at a side of the peripheral area PA. For example, the pad area PDA may be defined at a side of the substrate 100.

In an embodiment, the display apparatus 1 may include a first circuit board 300 and a second circuit board 400. In an embodiment, the first circuit board 300 and the second circuit board 400 may be located in the peripheral area PA.

In an embodiment, the first circuit board 300 may at least partially overlap the substrate 100. In an embodiment, the first circuit board 300 may at least partially overlap the pad area PDA. For example, the first circuit board 300 may be attached to the upper surface of the substrate 100 by using an anisotropic conductive film. As another example, the first circuit board 300 may also be attached to the upper surface of the substrate 100 by using an adhesive. However, the disclosure is not limited thereto. The first circuit board 300 may be attached to a lower surface of the substrate 100.

In an embodiment, the first circuit board 300 may at least partially overlap the second circuit board 400. For example, the first circuit board 300 may be attached to an upper surface of the second circuit board 400 by using an anisotropic conductive film. As another example, the first circuit board 300 may be attached to the upper surface of the second circuit board 400 by using an adhesive. However, the disclosure is not limited thereto. The first circuit board 300 may be attached to a lower surface of the second circuit board 400.

In an embodiment, the first circuit board 300 may be bent with respect to a bending axis BAX. In detail, at least a portion of the first circuit board 300 may be bent with respect to the bending axis BAX extending in the first direction (or x-direction). In an embodiment, as at least a portion of the first circuit board 300 is bent with respect to the bending axis BAX, the at least a portion of the first circuit board 300 and the second circuit board 400 may be located on the lower surface of the substrate 100. Accordingly, as the at least a portion of the first circuit board 300 and the second circuit board 400 are located on the lower surface of the substrate 100, the area of the peripheral area PA, which is a non-display area, may be reduced. In other words, the area of dead space may be reduced.

A display driver 350 may be arranged on the first circuit board 300. The first circuit board 300 may include the display driver 350. However, the disclosure is not limited thereto. The display apparatus 1 may include the display driver 350.

In an embodiment, the display driver 350 may receive control signals and power voltages and may generate signals and voltages for driving the display panel 200 and output the same. For example, the display driver 350 may be formed using an integrated circuit (IC). While the display driver 350 is arranged on a lower surface of the first circuit board 300 in FIG. 2, the disclosure is not limited thereto. In an embodiment, the display driver 350 may be arranged on an upper surface of the first circuit board 300. As another example, two display drivers 350 may be respectively located on the upper surface and the lower surface of the first circuit board 300.

In an embodiment, the second circuit board 400 may include a flexible printed circuit board (FPCB) that is bendable, a rigid printed circuit board (PCB) that is rigid and not easily bendable, or a complex PCB including both a rigid PCB and an FPCB.

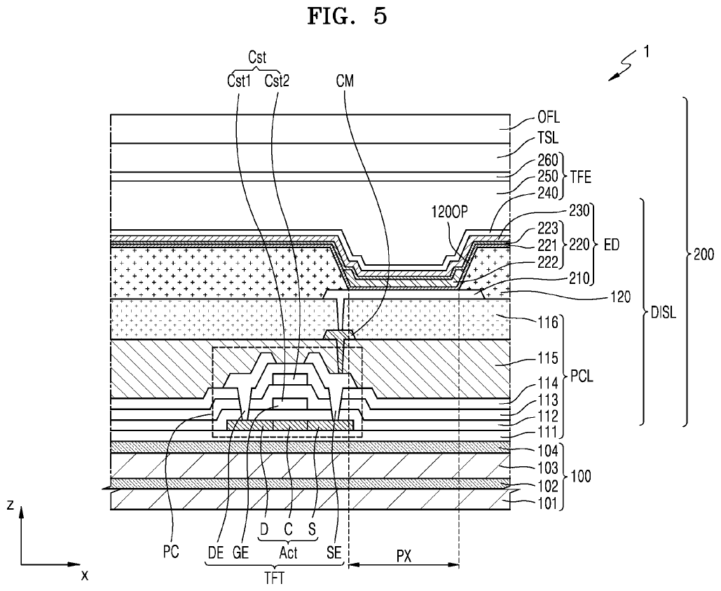

While not illustrated in the drawings, a touch sensor driver may be attached to the first circuit board 300 or the second circuit board 400. In an embodiment, the touch sensor driver may be formed using an IC. The touch sensor driver may be electrically connected to touch electrodes of a touch screen layer TSL (FIG. 5) of the display panel 200.

The touch screen layer TSL of the display panel 200 may detect a touch input by a user by using at least one of various touch methods such as a resistive film type method, a capacitive method, and the like. For example, in case that the touch screen layer TSL of the display panel 200 detects a touch input by a user by using a capacitive method, the touch sensor driver applies driving signals to driving electrodes among the touch electrodes. Whether the user has touched the display panel 200 may be determined by detecting voltages charged in mutual capacitance between the driving electrodes and sensing electrodes, by using the sensing electrodes from among the touch electrodes. A touch by a user may include a contact touch and a proximity touch. A contact touch refers to a direct contact by a user's finger or an object such as a pen on the cover window 500 arranged on the touch screen layer TSL. Similar to hovering, a proximity touch refers to an approach by the finger of a user or an object such as a pen in proximity to the cover window 500. The touch sensor driver transmits sensor data to a main processor based on the detected voltages, and by analyzing the sensor data, the main processor may calculate touch coordinates where a touch input has occurred.

In an embodiment, a power supplier may be further arranged on the first circuit board 300 or the second circuit board 400. The power supplier may supply driving voltages to drive pixels PX, a scan driver, and/or the display driver 350. The power supplier may be integrally formed as a single body with (or integral with) the display driver 350, and in this case, the power supplier and the display driver 350 may be formed as a single IC.

As another example, the first circuit board 300 or the second circuit board 400 may be electrically connected to a main circuit board. The main circuit board may include a main processor, such as an application processor (AP), including a central processing unit (CPU), a graphics processing unit (GPU), a memory, a communication chip, a digital signal processor (DSP), an image signal processor (ISP), and/or various types of interfaces. For example, as the first circuit board 300 is electrically connected to the second circuit board 400, and the second circuit board 400 is electrically connected to the main circuit board, the first circuit board 300 and the main circuit board may be electrically connected to each other.

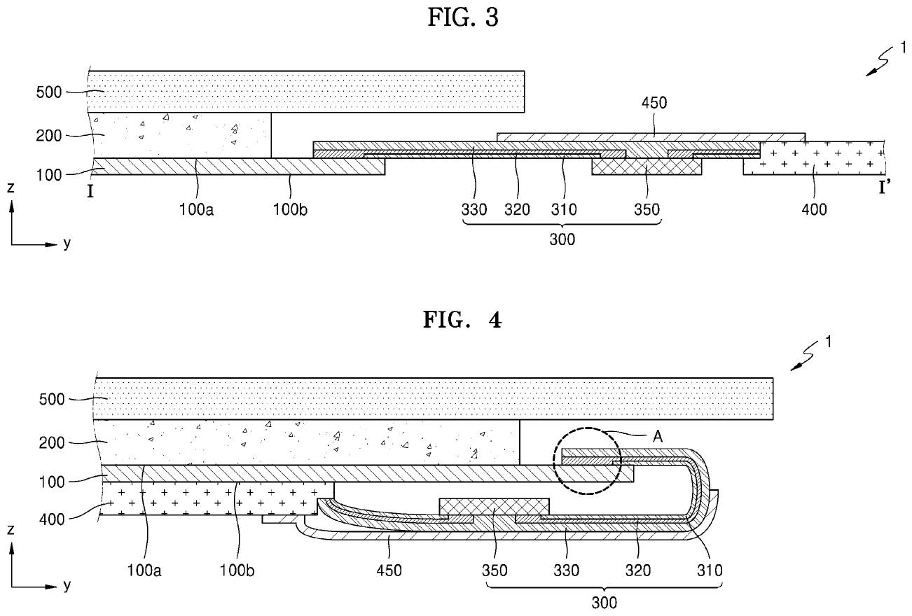

FIG. 3 is a cross-sectional view schematically illustrating a display apparatus according to an embodiment. FIG. 4 is a cross-sectional view schematically illustrating bending of the display apparatus of FIG. 3.

Referring to FIGS. 3 and 4, according to an embodiment, the display apparatus 1 may include the substrate 100, the display panel 200, and the cover window 500. In an embodiment, the cover window 500 may be arranged on a front surface of the display panel 200. Here, the term “front surface” may be defined as a surface on which a user may view an image provided by the display apparatus 1. Also, the display apparatus 1 may include the first circuit board 300, the second circuit board 400, and a cover layer 450. The display apparatus 1 may further include a bracket, a heat dissipation sheet, a battery, a camera module, a back surface cover, or the like.

The substrate 100 may include an insulating material such as glass, quartz, a polymer resin, or the like. The substrate 100 may be a rigid substrate or a flexible substrate that is bendable, foldable, rollable or the like.

In an embodiment, in case that the substrate 100 includes a polymer resin, the substrate 100 may include a polymer resin such as polyethersulfone, polyacrylate, polyether imide, polyethylene naphthalate, polyethylene terephthalate, polyphenylene sulfide, polyarylate, polyimide, polycarbonate, or cellulose acetate propionate.

In an embodiment, the cover window 500 may be arranged on an upper surface 100a of the substrate 100, and the display panel 200 may be between the substrate 100 and the cover window 500. For example, the substrate 100 may be included on the display panel 200. Here, the upper surface 100a of the substrate 100 may refer to a surface of the substrate 100 that is adjacent to the cover window 500, and a lower surface 100b of the substrate 100 may refer to a surface of the substrate 100, opposite to the upper surface 100a of the substrate 100.

Hereinafter, the term “upper surface” refers to a surface of the substrate 100 facing the cover window 500, for example, a surface facing a +z direction, and the term “lower surface” refers to a surface of the substrate 100 opposite to the upper surface, for example, a surface facing a −z direction.

The display panel 200 may include display elements. The display elements may include a light-emitting display panel including an emitting diode. In an embodiment, the display panel 200 may include an organic light-emitting display panel using an organic light-emitting diode (LED) including an organic emission layer, a micro LED display panel using a micro LED, a quantum dot light-emitting display panel using a quantum dot LED including a quantum dot emission layer, or an inorganic light-emitting display panel using an inorganic light-emitting element including an inorganic semiconductor.

In an embodiment, the display panel 200 may be a rigid display panel that is rigid and thus not easily bent or a flexible display panel that is flexible and easily bent, folded, or rolled. For example, the display panel 200 may be a foldable display panel, a curved display panel having a curved display surface, a bent display panel having areas curved except for a display surface, a rollable display panel that is rollable or unrollable, and a stretchable display panel.

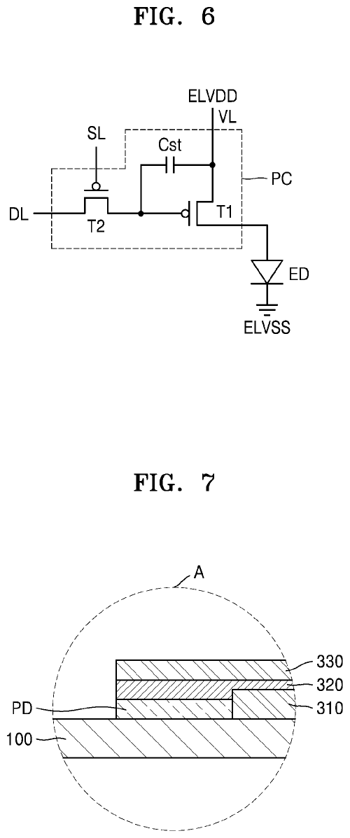

FIG. 5 is a cross-sectional view schematically illustrating a display apparatus according to an embodiment. FIG. 6 is an equivalent circuit diagram of a pixel circuit included in a display apparatus according to an embodiment.

Referring to FIG. 5, the display panel 200 may include a display layer DISL, an encapsulation layer TFE, the touch screen layer TSL, and an optical functional layer OFL. The display layer DISL may include a pixel circuit layer PCL, a pixel defining layer 120, and a light-emitting element ED.

The substrate 100 may have a multi-layer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104.

The pixel circuit layer PCL may be arranged on the substrate 100. The pixel circuit layer PCL may include a pixel circuit PC including a thin-film transistor TFT and a storage capacitor Cst. Also, the pixel circuit layer PCL may include a buffer layer 111, a first gate insulating layer 112, a second gate insulating layer 113, an interlayer insulating layer 114, a first planarization insulating layer 115, and a second planarization insulating layer 116, which are arranged below or/and above elements of the pixel circuit PC.

The buffer layer 111 may reduce or block penetration of foreign substances, moisture, or outside air from below the substrate 100 and may provide a flat surface on the substrate 100. The buffer layer 111 may include an inorganic insulating material such as silicon oxide, silicon oxynitride, and silicon nitride and may have a single layer or a multi-layer structure including the above-described material.

The thin-film transistor TFT may be arranged on the buffer layer 111. The thin-film transistor TFT on the buffer layer 111 may include a semiconductor layer Act, and the semiconductor layer Act may include polysilicon. As another example, the semiconductor layer Act may include amorphous silicon, an oxide semiconductor, or an organic semiconductor. The semiconductor layer Act may include a channel region C and a drain region D and a source region S arranged at both sides of the channel region C, respectively. A gate electrode GE of the thin-film transistor TFT may overlap the channel region C.

The gate electrode GE may include a low-resistance metal material. The gate electrode GE may include a conductive material including molybdenum (Mo), aluminum (Al), copper (Cu), titanium (Ti), and the like, and may have a multi-layer or single-layer structure including the above material.

The first gate insulating layer 112 between the semiconductor layer Act and the gate electrode GE may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). In this case, zinc oxide (ZnO_{X}) may include zinc oxide (ZnO) and/or zinc peroxide (ZnO₂).

The second gate insulating layer 113 may cover (or overlap) the gate electrode GE. The second gate insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). In this case, zinc oxide (ZnO_{X}) may include zinc oxide (ZnO) and/or zinc peroxide (ZnO₂).

An upper electrode Cst2 of the storage capacitor Cst may be arranged on the second gate insulating layer 113. The upper electrode Cst2 may overlap the gate electrode GE therebelow. The gate electrode GE and the upper electrode Cst2 overlapping each other with the second gate insulating layer 113 therebetween may form the storage capacitor Cst. For example, the gate electrode GE may function as a lower electrode Cst1 of the storage capacitor Cst.

As described above, the storage capacitor Cst and the thin-film transistor TFT may overlap each other. However, the disclosure is not limited thereto. In an embodiment, the storage capacitor Cst may not overlap the thin-film transistor TFT. For example, the lower electrode Cst1 of the storage capacitor Cst may be included as a separate element from the gate electrode GE.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers including the above-described material.

The interlayer insulating layer 114 may cover the upper electrode Cst2. The interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). In this case, zinc oxide (ZnO_{X}) may include zinc oxide (ZnO) and/or zinc peroxide (ZnO₂). The interlayer insulating layer 114 may include a single layer or multiple layers including the above-described inorganic insulating material.

A drain electrode DE and a source electrode SE of the thin-film transistor TFT may be located on the interlayer insulating layer 114. The drain electrode DE and the source electrode SE may be respectively electrically connected to the drain region D and the source region S via contact holes defined in insulating layers therebelow. The drain electrode DE and the source electrode SE may include a material having high conductivity. The drain electrode DE and the source electrode SE may include a conductive material including molybdenum (Mo), aluminum (Al), copper (Cu), titanium (Ti), and the like, and may have a single or multi-layer structure including the above material. According to an embodiment, the drain electrode DE and the source electrode SE may have a multi-layer structure of Ti/Al/Ti.

The first planarization insulating layer 115 may cover the drain electrode DE and the source electrode SE. The first planarization insulating layer 115 may include an organic insulating material, for example, a general-purpose polymer such as polymethylmethacrylate (PMMA) or polystyrene (PS), a polymer derivative having a phenol group, an acryl-based polymer, an imide-based polymer, an arylether-based polymer, an amide-based polymer, a fluorine-based polymer, a p-xylene-based polymer, a vinyl alcohol-based polymer, or a blend thereof.

The second planarization insulating layer 116 may be arranged on the first planarization insulating layer 115. The second planarization insulating layer 116 and the first planarization insulating layer 115 may include a same material, and the second planarization insulating layer 116 may include a general-purpose polymer such as PMMA or PS, a polymer derivative having a phenol group, an acryl-based polymer, an imide-based polymer, an arylether-based polymer, an amide-based polymer, a fluorine-based polymer, a p-xylene-based polymer, a vinyl alcohol-based polymer, or a blend thereof.

The light-emitting element ED may be arranged on the pixel circuit layer PCL having the above-described structure. The light-emitting element ED may include, for example, an organic light-emitting diode display. The light-emitting element ED may include a stacked structure including a pixel electrode 210, an intermediate layer 220, and an opposite electrode 230. The light-emitting element ED may emit light, such as red, green, or blue light, or red, green, blue, or white light. The light-emitting element ED emits light through an emission area, and the emission area may be defined as a pixel PX.

The pixel electrode 210 may be electrically connected to a contact metal CM arranged on the first planarization insulating layer 115 via a contact hole defined in the second planarization insulating layer 116. Also, the contact metal CM may be electrically connected to the thin-film transistor TFT via a contact hole defined in the first planarization insulating layer 115. Thus, the pixel electrode 210 may be electrically connected to the thin-film transistor TFT.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 210 may have a structure in which layers including ITO, IZO, ZnO, or In₂O₃ are above or below the above-described reflective layer.

The pixel defining layer 120 having an opening 120OP exposing at least a portion of the pixel electrode 210 may be arranged on the pixel electrode 210. The pixel defining layer 120 may include an organic insulating material and/or an inorganic insulating material. An emission area of light emitted from the light-emitting element ED may be defined by the opening 120OP of the pixel defining layer 120. For example, a size/width of the opening 120OP may correspond to a size/width of the emission area. Accordingly, the size and/or width of the pixel PX may be dependent on the size and/or width of the opening 120OP of the pixel defining layer 120.

The intermediate layer 220 may include an emission layer 222 formed to correspond to the pixel electrode 210. The emission layer 222 may include a polymer organic material or a low molecular weight organic material that emits light of a certain color. As another example, the emission layer 222 may include an inorganic light-emitting material or quantum dots.

A first functional layer 221 and a second functional layer 223 of the intermediate layer 220 may be arranged under and on the emission layer 222. The first functional layer 221 may include, for example, a hole transport layer (HTL), or an HTL and a hole injection layer (HIL). The second functional layer 223 may include an electron transport layer (ETL) and/or an electron injection layer (EIL). The first functional layer 221 and/or the second functional layer 223 may be a common layer entirely covering the substrate 100, similarly to the opposite electrode 230 to be described below.

The opposite electrode 230 may be arranged above the pixel electrode 210 and overlap the pixel electrode 210. The opposite electrode 230 may include a conductive material having a low work function. For example, the opposite electrode 230 may include a transparent layer (or semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. As another example, the opposite electrode 230 may further include a layer such as an ITO, IZO, ZnO, or In₂O₃ layer on the transparent layer (or semi-transparent layer) including the above-described material. The opposite electrode 230 may be integral with the substrate 100 to entirely cover the substrate 100.

The display panel 200 includes light-emitting elements ED that emit light through pixels PX and provide an image. For example, the display area DA (FIG. 1) may be defined by the light-emitting elements ED.

The encapsulation layer TFE may be arranged on the opposite electrode 230 of the light-emitting element ED and cover the light-emitting element ED of the display layer DISL. The encapsulation layer TFE may include at least one inorganic film layer and at least one organic film layer, and FIG. 5 illustrates, as an embodiment, the encapsulation layer TFE including a first inorganic film layer 240, an organic film layer 250, and a second inorganic film layer 260 that are sequentially stacked. However, the disclosure is not limited thereto. In an embodiment, the encapsulation layer TFE may include an encapsulation substrate facing the substrate 100 and a sealing member arranged between the encapsulation substrate and the substrate 100 to block a space between the substrate 100 and the encapsulation substrate from the outside.

The first inorganic film layer 240 and the second inorganic film layer 260 may include at least one inorganic material from among aluminum oxide, titanium oxide, tantalum oxide, hafnium oxide, zinc oxide, silicon oxide, silicon nitride, and silicon oxynitride. The organic film layer 250 may include a polymer-based material. Examples of the polymer-based material may include an acrylic resin, an epoxy resin, polyimide, polyethylene, and the like. In an embodiment, the organic film layer 250 may include acrylate. The organic film layer 250 may be formed by hardening a monomer or applying a polymer. The organic film layer 250 may be transparent.

The touch screen layer TSL including sensing electrodes may be arranged on the encapsulation layer TFE, and the optical functional layer OFL may be arranged on the touch screen layer TSL. The cover window 500 (FIG. 3) is arranged on the optical functional layer OFL, and the cover window 500 may be attached to the optical functional layer OFL by using an adhesive member. Although not illustrated in the drawings, an adhesive member may be arranged between the touch screen layer TSL and the optical functional layer OFL.

In an embodiment, the optical functional layer OFL may include an anti-reflection layer. The anti-reflection layer may reduce a reflectance of light (e.g., external light) incident from the outside through the display apparatus 1.

In an embodiment, the anti-reflection layer may include a polarization film. The polarization film may include a linear polarization plate and a phase delay film such as a quarter-wave (λ/4) plate. The phase delay film may be arranged on the touch screen layer TSL, and the linear polarization plate may be arranged on the phase delay film.

In an embodiment, the anti-reflection layer may include a filter layer including a black matrix and color filters. The color filters may be arranged in consideration of colors of light respectively emitted from pixels of the display apparatus 1. For example, the filter layer may include a color filter of a red, green or blue color. In an embodiment, the anti-reflection layer may include a destructive interference structure. The destructive interference structure may include a first reflective layer and a second reflective layer arranged on different layers from each other. First reflected light and second reflected light respectively reflected by the first reflective layer and the second reflective layer may destructively interfere with each other, and accordingly, external light reflectance may be reduced.

Referring to FIG. 6, the pixel circuit PC may include thin-film transistors TFT (FIG. 5) and the storage capacitor Cst and may be electrically connected to the light-emitting element ED. In an embodiment, the pixel circuit PC may include a driving thin-film transistor T1, a switching thin-film transistor T2, and the storage capacitor Cst.

The switching thin-film transistor T2 may be electrically connected to a scan line SL and a data line DL, and may be configured to transfer a data signal or a data voltage input via the data line DL to the driving thin-film transistor T1, according to a scan signal or a switching voltage input via the scan line SL. The storage capacitor Cst may be electrically connected to the switching thin-film transistor T2 and a driving voltage line VL and may store a voltage corresponding to a difference between a voltage received from the switching thin-film transistor T2 and a first power voltage ELVDD supplied to the driving voltage line VL.

The driving thin-film transistor T1 may be electrically connected to the driving voltage line VL and the storage capacitor Cst and may control a driving current flowing from the driving voltage line VL to the light-emitting element ED, in accordance with a voltage value stored in the storage capacitor Cst. An opposite electrode (e.g., a cathode) of the light-emitting element ED may receive a second power voltage ELVSS. The light-emitting element ED may emit light of brightness, according to a driving current.

While the pixel circuit PC including two thin-film transistors and a capacitor is described above, the disclosure is not limited thereto. For example, the pixel circuit PC may include three or more thin-film transistors and/or two or more storage capacitors. According to an embodiment, the pixel circuit PC may include seven thin-film transistors and a storage capacitor. The number of thin-film transistors and the number of storage capacitors may be variously modified according to the design of the pixel circuit PC. For convenience of description, however, the pixel circuit PC including two thin-film transistors and a storage capacitor will be described.

Referring back to FIGS. 3 and 4, the cover window 500 may be arranged to cover the front surface of the display panel 200. The cover window 500 may have a function of protecting the front surface of the display panel 200. The cover window 500 may be attached to the display panel 200 by using an adhesive layer. The adhesive layer may include an adhesive member, for example, an optical clear adhesive (OCA) or a pressure-sensitive adhesive (PSA). However, the disclosure is not limited thereto.

The cover window 500 may have a high transmittance to transmit light emitted from the display panel 200 and may have a small thickness to minimize the weight of the display apparatus 1. Also, the cover window 500 may have high rigidity and hardness to protect the display panel 200 from the external impact. In an embodiment, the cover window 500 may include glass. For example, the cover window 500 may include an ultra-thin glass (UTG) obtained by reinforcing the intensity thereof by using a chemical reinforcement method or a thermal reinforcement method. However, the disclosure is not limited thereto. In an embodiment, the cover window 500 may include a flexible window. The cover window 500 may protect the display panel 200 as the cover window 500 is easily bent by an external force without cracks generated therein.

Although not illustrated in the drawings, a lower protective layer may be arranged on the lower surface 100b of the substrate 100. The lower protective layer may be attached to the lower surface 100b of the substrate 100 in the form of a film by using an adhesive member. Any typical adhesive member may be used as the adhesive member, and the adhesive member may be, for example, an OCA or a PSA. The lower protective layer may protect the substrate 100 from the outside. For example, the lower protective layer may absorb physical impact from the outside and may block penetration of foreign substances or moisture into the display panel 200. In an embodiment, the lower protective layer may include an organic insulating material such as polyethylene terephthalate, polyimide, urethane acrylate, or the like. However, the disclosure is not limited thereto.

In an embodiment, the lower protective layer may further include a material blocking ultraviolet (UV) rays. For example, the lower protective layer may include a base resin, a UV ray absorbent, and inorganic particles. The UV ray absorbent and the inorganic particles may be distributed in a base resin. According to an embodiment, the base resin may include an acrylic resin, for example, urethane acrylate. However, the disclosure is not limited thereto, and any base resin that is optically transparent and distributes an UV absorbent and inorganic particles may be unlimitedly used in the lower protective layer. In an embodiment, the UV ray absorbent may include at least one of a benzotriazol compound, a benzophenone compound, a salicylic acid compound, a salicylate compound, a cyanoacrylate compound, a cinnamate compound, an oxanilide compound, a polystyrene compound, an azomethine compound, and a triazine compound. However, the disclosure is not limited thereto.

Although not illustrated in the drawings, a lower cover panel may be arranged on a lower surface of the lower protective layer. In an embodiment, the lower cover panel may include a light-blocking layer, a cushion layer, and a heat dissipation layer. A two-sided adhesive may be between any two elements from among the light-blocking layer, the cushion layer, and the heat dissipation layer.

The light-blocking layer of the lower cover panel may be arranged on a lower surface of the lower protective layer. The light-blocking layer may absorb light incident from the outside. In an embodiment, the light-blocking layer may include a black pigment or a black dye for absorbing external light. However, the disclosure is not limited thereto, and the light-blocking layer may include various materials that absorb external light.

The cushion layer may be arranged on a lower surface of the light-blocking layer. The cushion layer may absorb external light to prevent or minimize damage to the display panel 200. The cushion layer may include an elastic material. For example, the cushion layer may include a foam including a polymer resin such as polyurethane, polyethylene, polycarbonate, polypropylene, or polyolefin. As another example, the cushion layer may include an elastic material such as rubber and a sponge formed by various methods including a molding (e.g., foam molding or expansion molding) of an acrylic material or a urethane-based material. However, the materials are examples, and the cushion layer may include a material that has a high compressive stress and readily absorbs impact and vibration.

The heat dissipation layer may be arranged on a lower surface of the cushion layer. The heat dissipation layer may efficiently dissipate heat generated from the display panel 200 to the outside. For example, the heat dissipation layer may include a first heat dissipation layer including a thin metal film including copper, nickel, ferrite, silver, or the like, which has a high thermal conductivity and shields electromagnetic waves, and a second heat dissipation layer including graphite, carbon nanotubes, or the like.

The relative positions of the light-blocking layer, the cushion layer, and the heat dissipation layer constituting the lower cover panel may be variously modified.

In an embodiment, one end (or first end) of the first circuit board 300 may at least partially overlap the substrate 100, and the other end (or second end) of the first circuit board 300 may at least partially overlap the second circuit board 400. As another example, one end of the first circuit board 300 may be electrically connected to the substrate 100, and the other end of the first circuit board 300 may be electrically connected to the second circuit board 400.

In an embodiment, the first circuit board 300 may at least partially overlap the substrate 100 and may be attached to the upper surface 100a of the substrate 100. However, the disclosure is not limited thereto. For example, the first circuit board 300 may be attached to the lower surface 100b of the substrate 100.

In an embodiment, at least a portion of the first circuit board 300 may be bent with respect to the bending axis BAX (FIG. 2). In an embodiment, the first circuit board 300 may include flexible films 310 and 330, wires 320, and the display driver 350. The flexible films may include a first flexible film 310 and a second flexible film 330.

In an embodiment, it may be understood that the display apparatus 1 includes the first circuit board 300 and the display driver 350, and the display driver 350 is provided on a surface (e.g., an upper or lower surface 100a or 100b) of the first circuit board 300.

In an embodiment, the wires 320 may be arranged on the first flexible film 310. For example, the wires 320 may be arranged on a surface of the first flexible film 310, and the display driver 350 may be arranged on another surface of the first flexible film 310.

In an embodiment, the first flexible film 310 may include an insulating material. For example, the first flexible film 310 may include at least one of polystyrene, polyvinyl alcohol, polymethyl methacrylate, polyether sulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material constituting the first flexible film 310 may be variously changed, and the first flexible film 310 may also include fiber-reinforced plastic or the like.

In an embodiment, the wires 320 may include a metal. For example, the wires 320 may include at least one metal from among gold (Au), silver (Ag), aluminum (Al), molybdenum (Mo), chromium (Cr), titanium (Ti), nickel (Ni), neodymium (Nd), and copper (Cu), or an alloy of these metals. The wires 320 may include a single layer, but the disclosure is not limited thereto, and may include a multi-layer in which at least two of the metals and the alloys are stacked. However, the disclosure is not limited thereto.

In an embodiment, the second flexible film 330 may be arranged on the wires 320. For example, the second flexible film 330 may cover (or overlap) the wires 320. The second flexible film 330 and the first flexible film 310 may include a same material. However, the disclosure is not limited thereto. In an embodiment, the second flexible film 330 and the first flexible film 310 may include different materials. However, in case that the second flexible film 330 and the first flexible film 310 include different materials, the second flexible film 330 may include an insulating material.

In an embodiment, the display driver 350 may be arranged on the first flexible film 310. As described above, the display driver 350 may receive control signals and power voltages and may generate signals and voltages for driving the display panel 200 and output the same. For example, the display driver 350 may receive control signals and power voltages via the wires 320 and may generate signals and voltages for driving the display panel 200 and output the same.

FIG. 7 is a schematic enlarged view of region A of FIG. 4.

Referring to FIGS. 3, 4, and 7, in an embodiment, the first flexible film 310 and the second flexible film 330 may expose at least a portion of the wires 320. For example, at least a portion of the wires 320 may not be covered by the first flexible film 310 and/or the second flexible film 330 and may be exposed to the outside.

In an embodiment, a pad portion PD including pads may be arranged in the pad area PDA (FIG. 2). The pads included in the pad portion PD may electrically contact the wires 320 included in the first circuit board 300 to receive signals and voltages for driving the display panel 200 from the display driver 350. However, the disclosure is not limited thereto.

Referring back to FIGS. 3 and 4, in an embodiment, the first circuit board 300 and the second circuit board 400 may at least partially overlap each other, and the first circuit board 300 may be attached to an upper surface of the second circuit board 400. However, the disclosure is not limited thereto. For example, the first circuit board 300 may be attached to a lower surface of the second circuit board 400.

In an embodiment, the second circuit board 400 may have a step. The first circuit board 300 may be attached to the second circuit board 400 having a step. However, the disclosure is not limited thereto.

For example, the second circuit board 400 may be attached to the lower surface 100b of the substrate 100. In an embodiment, the second circuit board 400 may be attached to the lower surface 100b of the substrate 100 by using an adhesive member such as an OCA or a PSA. However, the disclosure is not limited thereto. A protective member, a heat dissipation member, or the like may be further arranged between the second circuit board 400 and the substrate 100.

In an embodiment, the cover layer 450 may overlap at least a portion of the first circuit board 300 and at least a portion of the second circuit board 400. In an embodiment, the cover layer 450 may at least partially cover the first circuit board 300. As another example, the cover layer 450 may at least partially cover the second circuit board 400.

In an embodiment, the cover layer 450 may include a conductive material. For example, the cover layer 450 may include a metal such as gold (Au), silver (Ag), aluminum (Al), molybdenum (Mo), chromium (Cr), titanium (Ti), nickel (Ni), neodymium (Nd), copper (Cu), or a conductive fiber, a conductive fabric, or the like.

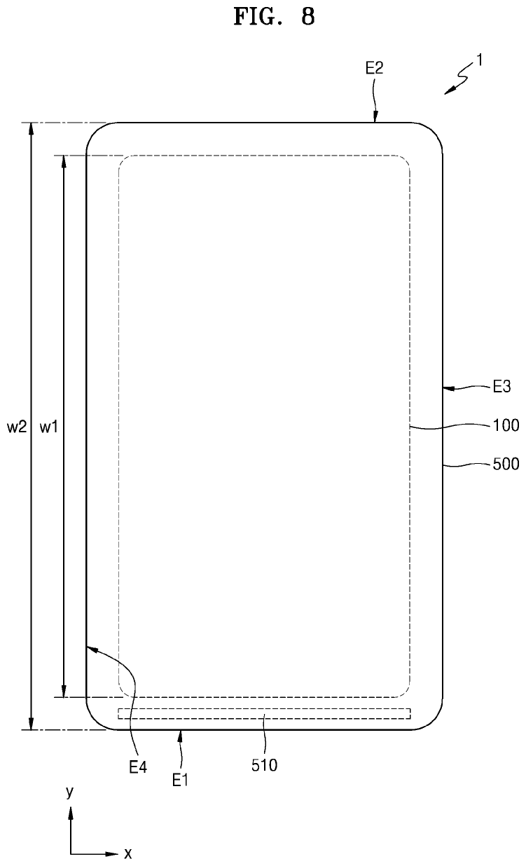

FIG. 8 is a plan view schematically illustrating a display apparatus according to an embodiment. The display panel 200 may be arranged between the substrate 100 and the cover window 500 of FIG. 8, but is omitted in FIG. 8 for convenience of description.

Referring to FIG. 8, in an embodiment, the cover window 500 may be arranged above the upper surface 100a (FIG. 4) of the substrate 100. In an embodiment, the substrate 100 and the cover window 500 may at least partially overlap each other.

In an embodiment, the substrate 100 may have a first width w1 in the second direction (or y-direction) intersecting the first direction (or x-direction). In an embodiment, the cover window 500 may have a second width w2 greater than the first width w1 of the substrate 100 in the second direction (or y-direction). For example, the cover window 500 may be wider than the substrate 100.

In an embodiment, the cover window 500 may have first to fourth edges E1 to E4. In an embodiment, the first edge E1 and the second edge E2 may be arranged symmetrically and in parallel to each other, and the third edge E3 and the fourth edge E4 may be arranged symmetrically and in parallel to each other.

In an embodiment, a first protruding member 510 may be provided on a lower surface of the cover window 500. In detail, the first protruding member 510 may be provided on a surface of the cover window 500 adjacent to the substrate 100.

In an embodiment, the first protruding member 510 may be located adjacent to the first edge E1 of the cover window 500. In an embodiment, the first protruding member 510 may extend in the first direction (or x-direction). Thus, the first protruding member 510 may extend along the first edge E1 of the cover window 500 in the first direction (or x-direction).

In an embodiment, the first protruding member 510 may be apart from the first edge E1 of the cover window 500 in the second direction (or y-direction). For example, the first protruding member 510 may be located adjacent to the first edge E1 of the cover window 500 and be apart from the first edge E1 of the cover window 500 by a certain distance in the second direction (or y-direction). Thus, the first protruding member 510 may be apart from the first edge E1 of the cover window 500 in the second direction (or y-direction) and extend along the first edge E1 in the first direction (or x-direction).

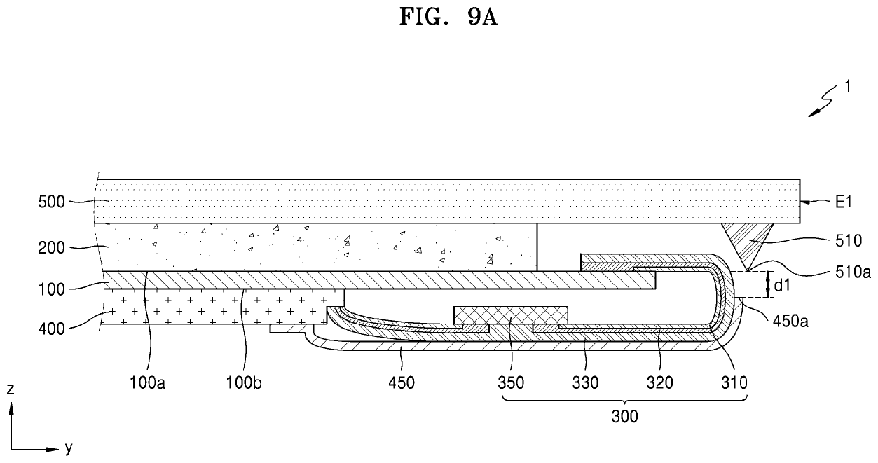

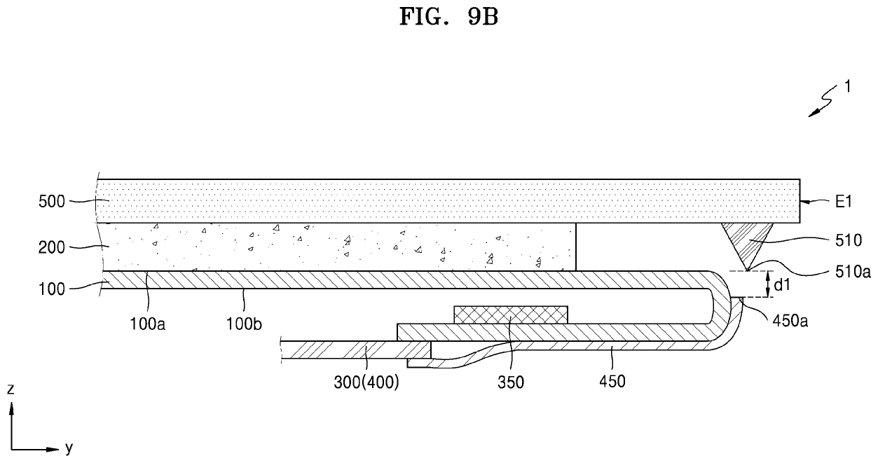

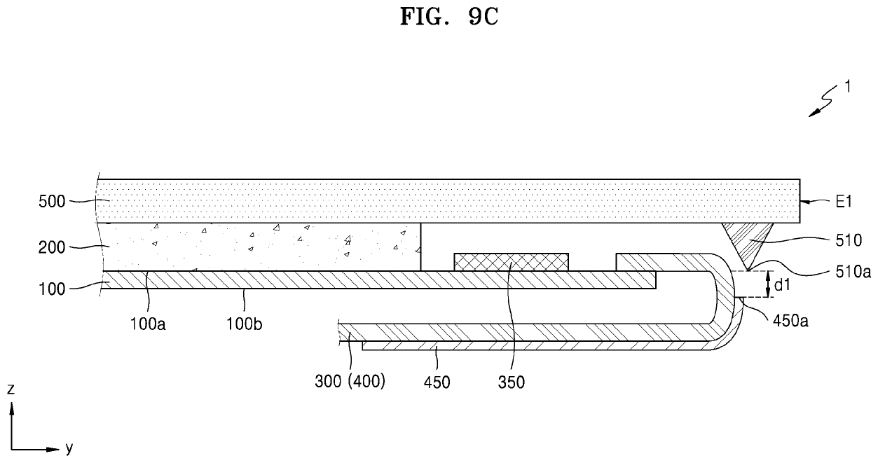

As another example, in an embodiment, the first protruding member 510 may be apart from the substrate 100 and/or the display panel 200 (FIG. 9A) in the second direction (or y-direction) and extend in the first direction (or x-direction).

FIG. 9A is a cross-sectional view schematically illustrating a display apparatus according to an embodiment. In detail, the embodiment of FIG. 9A is different from the embodiment of FIG. 4 in that the first protruding member 510 is provided on the lower surface of the cover window 500. As illustrated in FIG. 9A, like reference numerals as those of FIG. 4 denote like components, and thus, repetitive descriptions thereof will be omitted.

Referring to FIG. 9A, in an embodiment, the cover window 500 may be arranged on the upper surface 100a of the substrate 100, and the display panel 200 may be between the substrate 100 and the cover window 500.

In an embodiment, the first protruding member 510 may be arranged on the lower surface of the cover window 500. The lower surface of the cover window 500 may refer to a surface adjacent to the substrate 100.

In an embodiment, the first protruding member 510 may be apart from the display panel 200 in the second direction (or y-direction). For example, the first protruding member 510 may be between the display panel 200 and the first edge E1 of the cover window 500.

In an embodiment, the first protruding member 510 may at least partially overlap the cover layer 450. In an embodiment, an end 510a of the first protruding member 510 and an end 450a of the cover layer 450 may be spaced apart from each other by a first distance d1 in a third direction (or z-direction) which is perpendicular to the substrate 100. For example, the first protruding member 510 and the cover layer 450 may at least partially overlap each other, and the first protruding member 510 and the cover layer 450 may be apart from each other by the first distance d1 in the third direction (or z-direction). The first distance d1 may be from about 0.5 mm to about 1 mm.

A set is coupled or connected between the first edge E1 of the cover window 500 and the first protruding member 510, and in case that the first distance d1 is less than about 0.5 mm, the cover layer 450 may absorb an adhesive used to couple the set and thus cause a coupling defect of the set. On the other hand, in case that the first distance d1 is about 1 mm or more, a distance between the first protruding member 510 and the cover layer 450 is relatively large, and thus static electricity (or electrostatic current) may be transferred to a wire between the substrate 100 and the first circuit board 300.

Accordingly, in case that the first distance d1 is in a range of about 0.5 mm to about 1 mm, a coupling defect of the set may be prevented or minimized, and transfer of static electricity (or electrostatic current) to a wire between the substrate 100 and the first circuit board 300 may be prevented or minimized.

In an embodiment, the first protruding member 510 may include an insulating material such as glass, quartz, a polymer resin, or the like. In an embodiment, the first protruding member 510 may be integrally formed as a single body with (or integral with) the cover window 500. In this case, the first protruding member 510 may include glass. However, the disclosure is not limited thereto.

In an embodiment, the first protruding member 510 may include a conductive material. For example, the first protruding member 510 may include a metal such as gold (Au), silver (Ag), aluminum (Al), molybdenum (Mo), chromium (Cr), titanium (Ti), nickel (Ni), neodymium (Nd), copper (Cu), or a conductive fiber, a conductive fabric, or the like. In case that the first protruding member 510 includes a conductive material, the first protruding member 510 may be attached to the lower surface of the cover window 500 by using an adhesive member such as an OCA or a PSA.

In an embodiment, the end 510a of the first protruding member 510 may have an approximately downwardly pointed shape (e.g., −z direction). For example, the end 510a of the first protruding member 510 may have an approximately pointed shape in a −z direction. For example, a width of a portion of the first protruding member 510 adjacent to the cover window 500 may be relatively large, and the width of the first protruding member 510 may gradually decrease away from the cover window 500.

For example, as the end 510a of the first protruding member 510 has a pointed shape, static electricity (or electrostatic current) on the surface of the cover window 500 may be transferred to or collected at the end 510a of the first protruding member 510, and the static electricity (or the electrostatic current) transferred to or collected at the end 510a of the first protruding member 510 may be easily transferred to the cover layer 450 by air discharge (sparks).

In an embodiment, the cover layer 450 may release static electricity (or electrostatic current) to the outside by transferring static electricity (or electrostatic current) transferred from the first protruding member 510 to the second circuit board 400.

FIG. 9B is a cross-sectional view schematically illustrating a display apparatus according to an embodiment. In detail, the embodiment of FIG. 9B differs from the embodiment of FIG. 9A in that the display driver 350 is located on the substrate 100. As illustrated in FIG. 9B, like reference numerals as those of FIG. 9A denote like components, and thus, repetitive descriptions thereof will be omitted.

Referring to FIG. 9B, the display apparatus 1 may include the substrate 100, the display panel 200, a circuit board (the first circuit board 300 or the second circuit board 400), the cover layer 450, the cover window 500, and the first protruding member 510.

The display driver 350 may be provided on a surface (e.g., upper or lower surface 100a or 100b) of the substrate 100. While FIG. 9B illustrates that the display driver 350 is provided on the lower surface 100b of the substrate 100, the disclosure is not limited thereto. The display driver 350 may be provided on the upper surface 100a of the substrate 100.

In an embodiment, at least a portion of the substrate 100 may be bent with respect to the bending axis BAX (FIG. 2). As the at least a portion of the substrate 100 is bent with respect to the bending axis BAX, the area of the peripheral area PA adjacent to the first edge E1 may be reduced. For example, the dead space which is a non-display area may be reduced.

In an embodiment, the circuit board (the first circuit board 300 or the second circuit board 400) may at least partially overlap the substrate 100. For example, the circuit board (the first circuit board 300 or the second circuit board 400) may be attached to the upper surface 100a of the substrate 100 by using an anisotropic conductive film. However, the disclosure is not limited thereto. The circuit board (the first circuit board 300 or the second circuit board 400) may be attached to the lower surface 100b of the substrate 100 by using an anisotropic conductive film.

In an embodiment, the circuit board (the first circuit board 300 or the second circuit board 400) may be disposed on the lower surface 100b of the substrate 100. Accordingly, as the circuit board (the first circuit board 300 or the second circuit board 400) is located on the lower surface 100b of the substrate 100, the area of the peripheral area PA which is a non-display area may be reduced. For example, the area of the dead space may be reduced.

In an embodiment, the circuit board (the first circuit board 300 or the second circuit board 400) may be directly attached to the lower surface 100b of the substrate 100. As another example, a lower protective layer and/or a lower cover panel may be between the circuit board (the first circuit board 300 or the second circuit board 400) and the lower surface 100b of the substrate 100.

FIG. 9C is a cross-sectional view schematically illustrating a display apparatus according to an embodiment. In detail, the embodiment of FIG. 9C differs from the embodiment of FIG. 9A in that the display driver 350 is located on the substrate 100. As illustrated in FIG. 9C, like reference numerals as those of FIG. 9A denote like components, and thus, repetitive descriptions thereof will be omitted.

Referring to FIG. 9C, the display apparatus 1 may include the substrate 100, the display panel 200, a circuit board (the first circuit board 300 or the second circuit board 400), the cover layer 450, the cover window 500, and the first protruding member 510.

The display driver 350 may be provided on a surface (e.g., upper or lower surface 100a or 100b) of the substrate 100. While FIG. 9C illustrates that the display driver 350 is arranged on the upper surface 100a of the substrate 100, the disclosure is not limited thereto. The display driver 350 may be provided on the lower surface 100b of the substrate 100.

In an embodiment, the circuit board (the first circuit board 300 or the second circuit board 400) may at least partially overlap the substrate 100. For example, the circuit board (the first circuit board 300 or the second circuit board 400) may be attached to the upper surface 100a of the substrate 100 by using an anisotropic conductive film. However, the disclosure is not limited thereto. The circuit board (the first circuit board 300 or the second circuit board 400) may be attached to the lower surface 100b of the substrate 100 by using an anisotropic conductive film.

In an embodiment, at least a portion of the circuit board (the first circuit board 300 or the second circuit board 400) may be bent with respect to the bending axis BAX (FIG. 2). As the at least a portion of the circuit board (the first circuit board 300 or the second circuit board 400) is bent with respect to the bending axis BAX, the area of the peripheral area PA adjacent to the first edge E1 may be reduced. For example, the dead space which is a non-display area may be reduced.

In an embodiment, as at least a portion of the circuit board (the first circuit board 300 or the second circuit board 400) is bent with respect to the bending axis BAX, the at least a portion of the circuit board (the first circuit board 300 or the second circuit board 400) may be located on the lower surface 100b of the substrate 100.

In an embodiment, the circuit board (the first circuit board 300 or the second circuit board 400) may be directly attached to the lower surface 100b of the substrate 100. As another example, a lower protective layer and/or a lower cover panel may be between the circuit board (the first circuit board 300 or the second circuit board 400) and the lower surface 100b of the substrate 100.

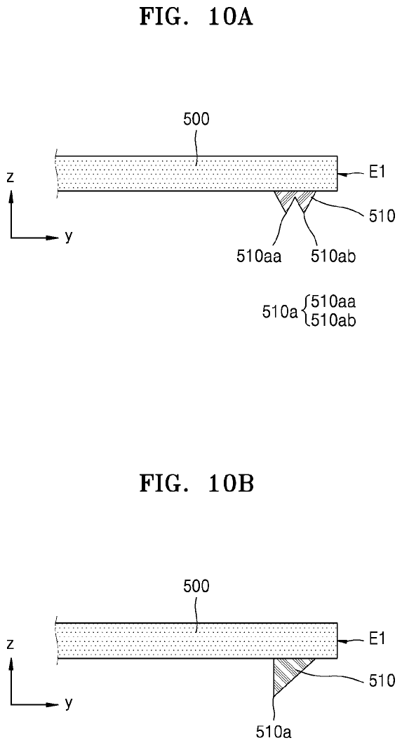

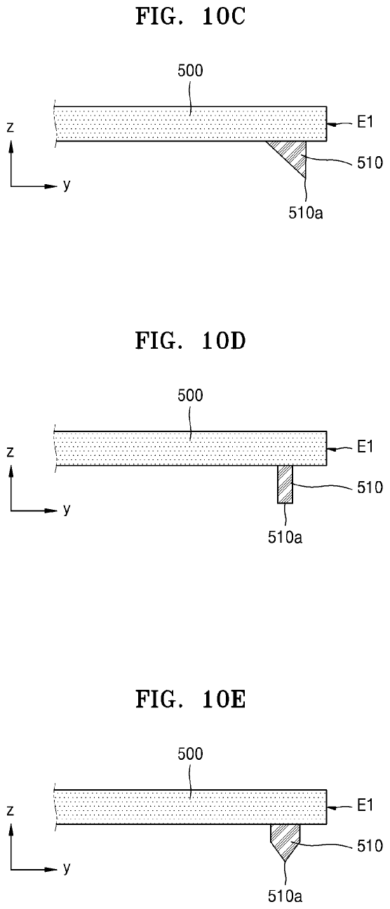

FIGS. 10A to 10E are schematic diagrams for describing a schematic shape of a first protruding member of a display apparatus according to an embodiment.

Referring to FIG. 10A, the first protruding member 510 may be arranged on the lower surface of the cover window 500. In an embodiment, the first protruding member 510 may include two ends 510a. For example, the first protruding member 510 may include a first end 510aa and a second end 510ab. In an embodiment, the first end 510aa and the second end 510ab of the first protruding member 510 may have an approximately downwardly pointed shape (e.g., −z direction).

Referring to FIG. 10B, the end 510a of the first protruding member 510 may have an approximately downwardly pointed shape (e.g., −z direction). In an embodiment, a slope of a surface of the first protruding member 510, the surface being adjacent to the first edge E1 of the cover window 500 may be relatively gentle, and a slope of a surface of the first protruding member 510, the surface being adjacent to the display panel 200, may be relatively steep.

On the other hand, referring to FIG. 10C, in an embodiment, a slope of a surface of the first protruding member 510, the surface being adjacent to the first edge E1 of the cover window 500 may be relatively steep, and a slope of a surface, of the first protruding member 510, the surface being adjacent to the display panel 200, may be relatively gentle.

Referring to FIG. 10D, in an embodiment, the first protruding member 510 may be arranged under the cover window 500, and the first protruding member 510 may have a rectangular or square shape. As another example, the first protruding member 510 may have other shapes such as a trapezoidal shape or a rhombic shape.

Referring to FIG. 10E, the end 510a of the first protruding member 510 may have an approximately downwardly pointed shape (e.g., −z direction), specifically, in a pentagon shape.

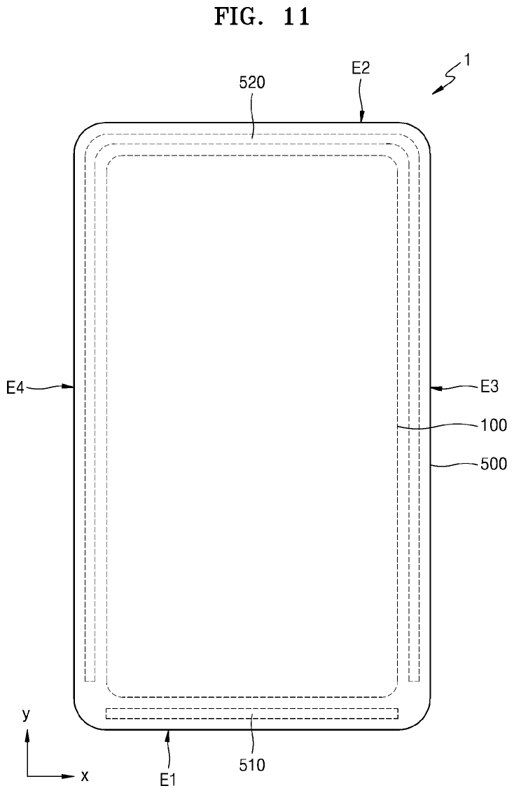

FIG. 11 is a plan view schematically illustrating a display apparatus according to an embodiment. The embodiment of FIG. 11 is different from the embodiment of FIG. 8 in that a second protruding member 520 is further arranged on the lower surface of the cover window 500. In FIG. 11, like reference numerals as those of FIG. 8 denote like components, and thus, repetitive descriptions thereof will be omitted.

Referring to FIG. 11, in an embodiment, the cover window 500 may be arranged on the upper surface 100a (FIG. 4) of the substrate 100. In an embodiment, the substrate 100 and the cover window 500 may at least partially overlap each other.

In an embodiment, the cover window 500 may have the first to fourth edges E1 to E4. In an embodiment, the first edge E1 and the second edge E2 may be arranged symmetrically and in parallel to each other, and the third edge E3 and the fourth edge E4 may be arranged symmetrically and in parallel to each other.

In an embodiment, the first protruding member 510 may be provided on the lower surface of the cover window 500. In detail, the first protruding member 510 may be provided on a surface of the cover window 500 adjacent to the substrate 100.

In an embodiment, the first protruding member 510 may be located adjacent to the first edge E1 of the cover window 500. In an embodiment, the first protruding member 510 may extend in the first direction (or x-direction). Thus, the first protruding member 510 may extend along the first edge E1 of the cover window 500 in the first direction (or x-direction).

In an embodiment, the second protruding member 520 may be provided on the lower surface of the cover window 500. In detail, the second protruding member 520 may be provided on a surface of the cover window 500 adjacent to the substrate 100.

In an embodiment, the first protruding member 510 and the second protruding member 520 may not overlap each other. In an embodiment, the second protruding member 520 may be located adjacent to the second edge E2, the third edge E3, and the fourth edge E4 of the cover window 500. In an embodiment, the first protruding member 510 may extend in the first direction (or x-direction) and/or the second direction (or y-direction). For example, a portion of the second protruding member 520 adjacent to the second edge E2 of the cover window 500 may extend in the first direction (or x-direction), and portions of the second protruding member 520 adjacent to the third edge E3 and the fourth edge E4 of the cover window 500 may extend in the second direction (or y-direction).

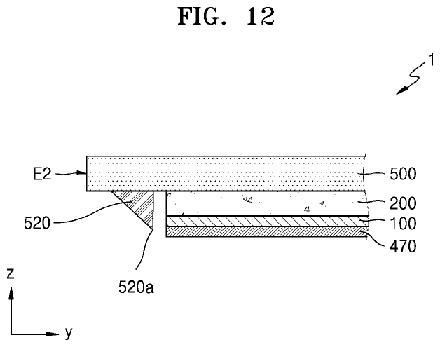

In an embodiment, the second protruding member 520 located under the cover window 500 may partially surround the substrate 100 and/or the display panel 200 (FIG. 12) in a loop shape having an open side. However, the disclosure is not limited thereto.

Static electricity (or electrostatic current) may flow along a surface of the cover window 500. For example, the static electricity (or electrostatic current) flowing along the surface of the cover window 500 may be transferred to an adhesive member that bonds or attaches the display panel 200 and the cover window 500 to each other. In case that the static electricity (or electrostatic current) is transferred to the adhesive member for bonding the display panel 200 and the cover window 500 to each other, the cover window 500 may be peeled off or detached from the display panel 200.

In an embodiment, the second protruding member 520 may be arranged on the lower surface of the cover window 500, and the second protruding member 520 may be provided along a circumference of the substrate 100 and/or the display panel 200 to thereby prevent or minimize transfer of static electricity (or electrostatic current) to the adhesive member bonding the display panel 200 and the cover window 500 to each other, thereby preventing or minimizing exfoliation of the cover window 500 from the display panel 200.

Also, in an embodiment, the second protruding member 520 may be arranged on the lower surface of the cover window 500, and the second protruding member 520 may be provided along a circumference of the substrate 100 and/or the display panel 200 to thereby prevent or minimize damage to the encapsulation layer TFE (FIG. 5) and/or the light-emitting element ED (FIG. 5) due to the static electricity (or the electrostatic current).

In an embodiment, the second protruding member 520 may be provided on a portion of the lower surface of the cover window 500 adjacent to the second edge E2 of the cover window 500, and the second protruding member 520 may not be provided on a portion of the lower surface of the cover window 500 adjacent to the third edge E3 and/or the fourth edge E4 of the cover window 500. As another example, other various modifications may also be made; for example, the second protruding member 520 may be provided on a portion of the lower surface of the cover window 500 adjacent to the third edge E3 and/or the fourth edge E4 of the cover window 500, and the second protruding member 520 may not be provided on a portion of the lower surface of the cover window 500 adjacent to the second edge E2 of the cover window 500.

In an embodiment, the first protruding member 510 and the second protruding member 520 may be integrated as a single body (or integral with each other). However, the disclosure is not limited thereto.

FIG. 12 is a cross-sectional view schematically illustrating a display apparatus according to an embodiment. As illustrated in FIG. 12, like reference numerals as those of FIG. 4 denote like components, and thus, repetitive descriptions thereof will be omitted. Also, the second protruding member 520 of FIG. 12 is located adjacent to the second edge E2 of the cover window 500, and as described with reference to FIG. 11, the second protruding member 520 may also be arranged on the lower surface of the cover window 500 adjacent to the third edge E3 and/or the fourth edge E4 of the cover window 500.

Referring to FIG. 12, the display apparatus 1 may include the substrate 100, the display panel 200, and the cover window 500. Also, the display apparatus 1 may further include a shielding film 470 arranged on the lower surface 100b of the substrate 100.

In an embodiment, the second protruding member 520 may be arranged on the lower surface of the cover window 500. The lower surface of the cover window 500 may refer to a surface thereof adjacent to the substrate 100.

In an embodiment, the second protruding member 520 may be apart from the display panel 200 in the second direction (or y-direction). For example, the second protruding member 520 may be between the display panel 200 and the second edge E2 of the cover window 500.

Also, in an embodiment, although not illustrated, in case that the second protruding member 520 is arranged on a portion of the lower surface of the cover window 500 adjacent to the third edge E3 and/or the fourth edge E4 of the cover window 500, the second protruding member 520 may be apart from the display panel 200 in the first direction (or x-direction). For example, the second protruding member 520 may be between the display panel 200 and the third edge E3 (and/or the fourth edge E4) of the cover window 500.

In an embodiment, an end 520a of the second protruding member 520 may have an approximately downwardly pointed shape (e.g., −z direction). For example, the end 520a of the second protruding member 520 may have an approximately downwardly pointed shape in a −z direction. For example, a width of a portion of the second protruding member 520 adjacent to the cover window 500 may be relatively large, and the width of the second protruding member 520 may gradually decrease away from the cover window 500.

In an embodiment, a slope of a surface, of the second protruding member 520 adjacent to the second edge E2 of cover window 500 may be relatively gentle, and a slope of a surface of the second protruding member 520, the surface being adjacent to the display panel 200, may be relatively steep. In detail, a slope of a surface of the second protruding member 520 adjacent to the second, third, and fourth edges E2, E3, and E4 of the cover window 500 may be relatively gentle, and a slope of a surface of the second protruding member 520, the surface being adjacent to the display panel 200, may be relatively steep. However, the disclosure is not limited thereto. The second protruding member 520 may have various shapes as described above with reference to FIGS. 10A to 10E.

In an embodiment, the shielding film 470 may be arranged on the lower surface 100b of the substrate 100. For example, the shielding film 470 may be directly arranged on the lower surface 100b of the substrate 100. However, the disclosure is not limited thereto. In an embodiment, an additional component may be further included between the shielding film 470 and the substrate 100.

In an embodiment, the shielding film 470 may include a metal such as gold (Au), silver (Ag), aluminum (Al), molybdenum (Mo), chromium (Cr), titanium (Ti), nickel (Ni), neodymium (Nd), copper (Cu), or a conductive fiber, a conductive fabric, or the like.

In an embodiment, as the end 520a of the second protruding member 520 has a pointed shape, static electricity (or electrostatic current) on the surface of the cover window 500 may be transferred to or collected at the end 520a of the second protruding member 520, and the static electricity (or electrostatic current) transferred to or collected at the end 520a of the second protruding member 520 may be easily transferred to the shielding film 470 by air discharge (sparks).

According to the embodiment of the disclosure as described above, a display apparatus in which a protruding member is arranged on a lower surface of a cover window to thus prevent or minimize transfer of static electricity (or electrostatic current) to wires may be implemented. However, the scope of the disclosure is not limited by the above-described effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a cover window arranged on an upper surface of the substrate;
a first circuit board that at least partially overlaps the substrate and is at least partially bendable;
a cover layer at least partially overlapping the first circuit board; and
a first protruding member arranged on a lower surface of the cover window.

2. The display apparatus of claim 1, wherein the first protruding member at least partially overlaps the cover layer.

3. The display apparatus of claim 2, wherein an end of the first protruding member and an end of the cover layer are spaced apart from each other by a first distance in a direction perpendicular to the substrate.

4. The display apparatus of claim 1, wherein the first protruding member extends in a first direction.

5. The display apparatus of claim 4, wherein the first protruding member is spaced apart from a first edge of the cover window in a second direction intersecting the first direction.

6. The display apparatus of claim 1, wherein the first protruding member is integral with the cover window.

7. The display apparatus of claim 1, wherein the first protruding member comprises a conductive material.

8. The display apparatus of claim 1, wherein the first circuit board comprises a flexible film, a wire, and a display driver.

9. The display apparatus of claim 1, further comprising:
a second circuit board arranged on a lower surface of the substrate.

10. The display apparatus of claim 9, wherein the first circuit board at least partially overlaps the second circuit board.

11. The display apparatus of claim 9, wherein the cover layer at least partially overlaps the second circuit board.

12. The display apparatus of claim 11, wherein the cover layer comprises a conductive material.

13. The display apparatus of claim 4, further comprising a display panel between the substrate and the cover window.

14. The display apparatus of claim 13, wherein the first protruding member is spaced apart from the display panel in the second direction.

15. The display apparatus of claim 14, further comprising:
a second protruding member arranged on the lower surface of the cover window.

16. The display apparatus of claim 15, wherein the second protruding member is spaced apart from the display panel.

17. The display apparatus of claim 15, wherein the second protruding member is integral with the cover window.

18. The display apparatus of claim 15, wherein the second protruding member comprises a conductive material.

19. The display apparatus of claim 15, wherein the second protruding member is integral with the first protruding member.

20. The display apparatus of claim 1, further comprising a shielding film arranged on a lower surface of the substrate.
